(19) United States
(12) Patent Application Publication
(10) Pub. No.: US 2020/0029403 A1
(43) Pub. Date: Jan. 23, 2020

(54) ENCAPSULATED LED ENGINE AND A PROCESS FOR ENCAPSULATING AN LED ENGINE

(71) Applicant: Appleton Grp LLC, Rosemont, IL (US)

(72) Inventors: Bharat Chaturvedi, Pune (IN); Sumit Kumar, Pune (IN)

(21) Appl. No.: 16/381,884

(22) Filed: Apr. 11, 2019

(30) Foreign Application Priority Data
Jul. 18, 2018 (IN) 201821026895

(51) Int. Cl. H05B 33/08; H05K 1/02; H01L 33/58; H01L 33/52

(52) U.S. Cl. CPC H05B 33/0806; H01L 33/52; H01L 33/58; H05K 1/0274

(57) ABSTRACT

An encapsulated LED engine including a printed circuit board, a plurality of LED arrays, each of the LED arrays mounted on the printed circuit board, and electrically connected to each other wherein, in each of the LED arrays, LEDs are electrically connected to each other; and an encapsulation layer configured to encapsulate each of the LED arrays and the electrical connections therebetween, wherein the encapsulation layer includes at least one blister configured to encapsulate at least one LED, and is further configured to transform the light emitted by said LED into a desired light beam pattern; and at least one planar portion configured to encapsulate at least one electrical connection formed on the printed circuit board.

### RELATED APPLICATIONS

This application claims priority to Indian Patent Application No. 201821026895 entitled “AN ENCAPSULATED LED ENGINE AND A PROCESS FOR ENCAPSULATING AN LED ENGINE” filed on Jul. 18, 2018, the contents which are incorporated by reference herein in their entirety.

### FIELD

The present disclosure relates to the field of luminaires. More particularly, the present disclosure relates to the field of LED engines used in luminaires.

### Definitions

As used in the present disclosure, the following terms are generally intended to have the meaning as set forth below, except to the extent that the context in which they are used indicates otherwise.

The expression “LED engine” used hereinafter in this specification refers to, but is not limited to, an integrated assembly comprising LED arrays (modules), an LED driver, and other optical, thermal, mechanical and electrical components. More specifically, an LED engine includes an LED chip mounted on a circuit board that has electrical connections and mechanical fixings, and is ready to be fixed in a luminaire.

The expression “Zone-1” used hereinafter in this specification refers to, but is not limited to, an area in which an explosive atmosphere is likely to occur occasionally in normal operation. It may exist because of repair, maintenance operations, or leakage.

The expression “Zone-2” used hereinafter in this specification refers to, but is not limited to, an area in which an explosive atmosphere is not likely to occur in normal operation but, if it does occur, will persist for a short period only. These areas become hazardous only in an event of an accident or some unusual operating condition.

These definitions are in addition to those expressed in the art.

### BACKGROUND

The background information herein below relates to the present disclosure but is not necessarily prior art.

LED luminaires are widely used in industrial environments. However, in industrial environments, where an explosive atmosphere persists between 10 and 1000 hours a year due to the nature of the products being manufactured or processed, the electrical discharges are required to be tightly controlled in order to prevent explosions. It is mandatory to ensure that the electrical products used in such explosive atmospheres should eliminate the potential for electrical discharges such as sparks or arcs.

Conventionally, the lighting fixtures, which are used in zone-1 applications, are flame proof fixtures. These flame proof fixtures are usually heavy and bulky which is not desired. Further, completely encapsulated LED engines were introduced, as an alternative to conventional flame proof structures and other known conventional techniques, for preventing electrical discharges considering the complexity and difficulty involved with other known conventional techniques. However, in order to fulfill the requirement of the desired lumen output, multiple LED arrays are needed in a single LED engine of an LED luminaire, thereby increasing the number of interconnections required and the quantity of wires joined to light up the LED arrays. The increased number of interconnections and wiring also shrinks the reliability of the conventional encapsulated LED engine. Further, various protection methods are known in the art to make the LED luminaire compatible for hazardous industrial environments. However, such methods lower the efficacy and adversely affect the beam pattern generated by LED arrays. Further, such conventional methods are costly.

Therefore, there is felt a need of an encapsulated LED engine that alleviates the abovementioned drawbacks and is compatible for hazardous industrial environments.

### Objects

Some of the objects of the present disclosure, which at least one embodiment herein satisfies, are as follows:

An object of the present disclosure is to provide an encapsulated LED engine and a process of making the encapsulated LED engine that are cost effective.

Still another object of the present disclosure is to provide an encapsulated LED engine which has reduced surface temperature.

Yet another object of the present disclosure is to provide an encapsulated LED engine which has a simple configuration.

Still another object of the present disclosure is to provide an encapsulated LED engine which has improved life.

Yet another object of the present disclosure is to provide an encapsulated LED engine that is not prone to early de-lamination due to frequent exposure to thermal shocks.

Still another object of the present disclosure is to provide an encapsulated LED engine that eliminates the requirement of secondary optics.

Yet another object of the present disclosure is to provide an encapsulated LED engine that is modular.

Still another object of the present disclosure is to provide an encapsulated LED engine that better utilizes the space of the printed circuit board.

Yet another embodiment of the present disclosure is to provide an encapsulated LED engine that eliminates formation of air bubbles;

Still another object of the present disclosure is to provide an encapsulated LED engine that is light in weight.

Yet another object of the present disclosure is to provide a process for encapsulating an LED engine that does not affect the beam pattern of the LED arrays.

Other objects and advantages of the present disclosure will be more apparent from the following description, which is not intended to limit the scope of the present disclosure.

### SUMMARY

The present disclosure envisages an encapsulated LED engine. The LED engine comprises a printed circuit board, a plurality of LED arrays, and an encapsulation layer.

Each of the plurality of LED arrays is mounted on the printed circuit board, and is electrically connected to each other. Each of the LED arrays includes a plurality of LEDs electrically connected to each other.

The encapsulation layer is configured to encapsulate each of the LED arrays and the electrical connections therebetween. The encapsulation layer includes at least one blister and at least one planar portion. The blister is configured to encapsulate at least one LED, and is further configured to transform the light emitted by the LED into a desired light beam pattern. The planar portion of the encapsulation layer is configured to encapsulate at least one electrical connection formed on the printed circuit board.

In an embodiment, the blister has transmittance in the range of 90% to 96%.

The present disclosure further envisages a process for encapsulating an LED engine having LED arrays and a printed circuit board. The LED arrays are mounted on the printed circuit board. The process comprises coating a primer on the LED arrays to obtain a primer coated LED engine. The so obtained primer coated LED engine is heated to a first predetermined temperature to obtain a heated primer coated LED engine.

The heated primer coated LED engine is disposed in a mould. A silicone mixture is injected into the mould cavity of the mould at a predetermined pressure to encapsulate the LED array. The silicone mixture is prepared by admixing a first silicone and a second silicone, and stirring the admixture of the first silicone and the second silicone in a vacuum machine. The first silicone and the second silicone have different viscosities.

Subsequent to injecting the silicone mixture in the mould, the mould is heat treated in a thermal chamber for a predetermined time period.

The heat treated mould is cooled to a second predetermined temperature.

Subsequently, the mould is opened to obtain an encapsulated LED engine.

### BRIEF DESCRIPTION OF THE ACCOMPANYING DRAWING

An encapsulated LED engine, of the present disclosure, will now be described with the help of the accompanying drawing, in which:

FIG. 1 illustrates a top view of an encapsulated LED engine, in accordance with an embodiment of the present disclosure;

FIG. 2 illustrates an isometric view of the encapsulated LED engine, in accordance with another embodiment of the present disclosure;

FIG. 3 illustrates an isometric view of the encapsulated LED engine, in accordance with yet another embodiment of the present disclosure;

FIG. 4 illustrates a top view of the encapsulated LED engine, in accordance with yet another embodiment of the present disclosure;

FIG. 5 illustrates a sectional view of the encapsulated LED engine, in accordance with yet another embodiment of the present disclosure; and

FIG. 6 illustrates an exploded view of the encapsulated LED engine of the present disclosure.

### LIST OF REFERENCE NUMERALS

100—LED engine
105—Printed circuit board
108—LED array
110—Encapsulation layer
115—Blisters
120—Planar portion
125—LEDs of the LED engine
130—Electrical wires
135—Electrical connections

### DETAILED DESCRIPTION

Embodiments, of the present disclosure, will now be described with reference to the accompanying drawing.

Embodiments are provided so as to thoroughly and fully convey the scope of the present disclosure to the person skilled in the art. Numerous details, are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used, in the present disclosure, is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open ended transitional phrases and therefore specify the presence of stated features, integers, steps, operations, elements, modules, units and/or components, but do not forbid the presence or addition of one or more other features, integers, steps, operations, elements, components, and/or groups thereof. The particular order of steps disclosed in the method and process of the present disclosure is not to be construed as necessarily requiring their performance as described or illustrated. It is also to be understood that additional or alternative steps may be employed.

When an element is referred to as being “mounted on,” “engaged to,” “connected to,” or “coupled to” another element, it may be directly on, engaged, connected or coupled to the other element. As used herein, the term “and/or” includes any and all combinations of one or more of the associated listed elements.

The terms first, second, third, etc., should not be construed to limit the scope of the present disclosure as the aforementioned terms may be only used to distinguish one element, component, region, layer or section from another component, region, layer or section. Terms such as first, second, third etc., when used herein do not imply a specific sequence or order unless clearly suggested by the present disclosure.

Terms such as “inner,” “outer,” “beneath,” “below,” “lower,” “above,” “upper,” and the like, may be used in the present disclosure to describe relationships between different elements as depicted from the figures.

The present disclosure envisages an encapsulated LED engine.

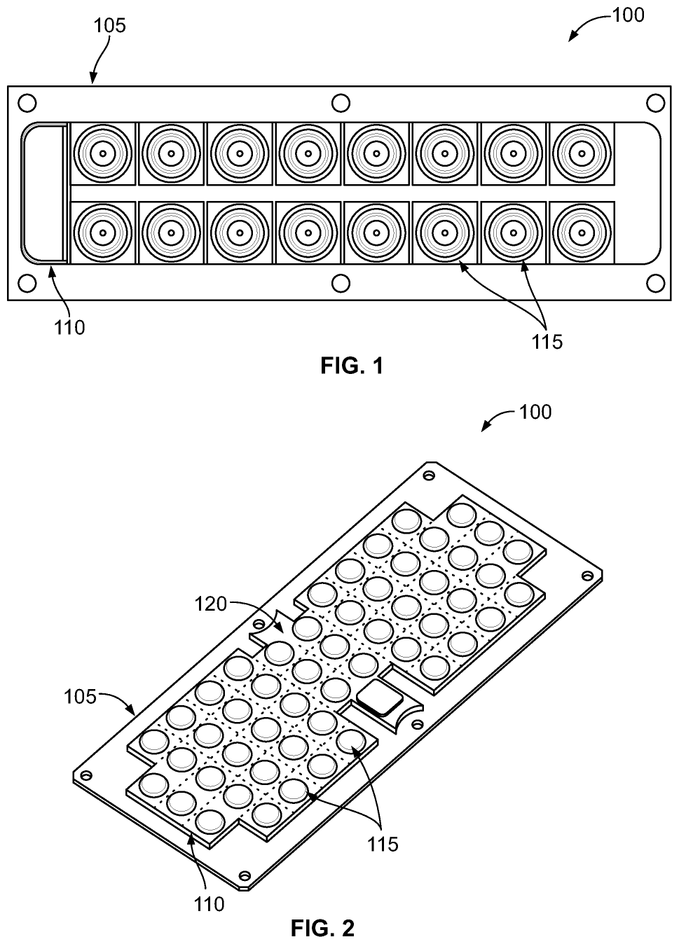

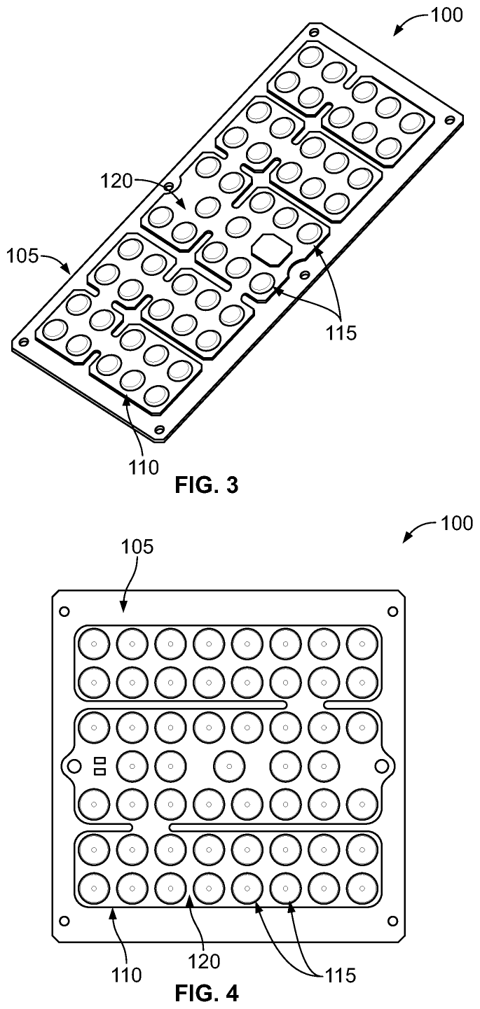

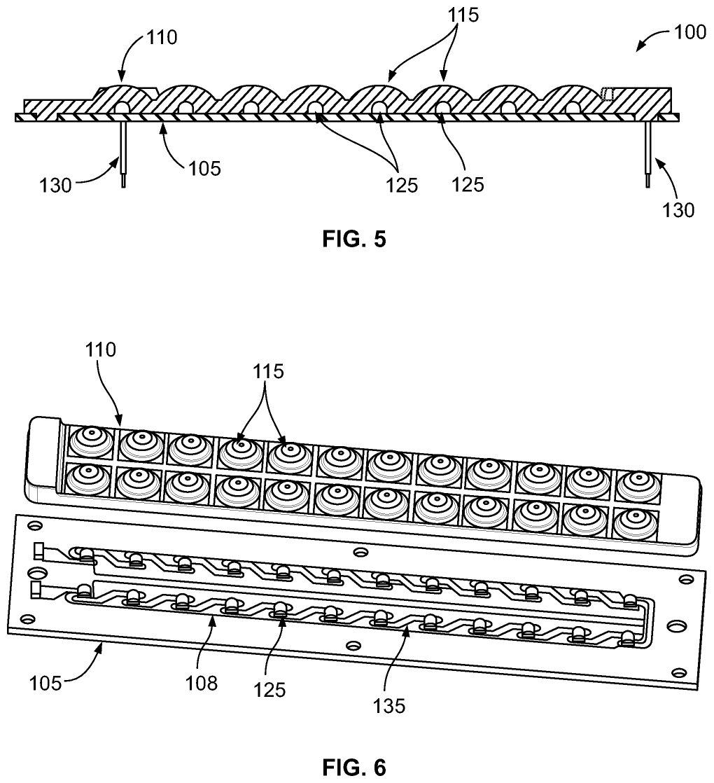

The LED engine, of the present disclosure, is now described with reference to FIG. 1 through FIG. 6.

Referring to FIG. 1 to FIG. 6, an LED engine 100 comprises a printed circuit board 105, a plurality of LED arrays 108, and an encapsulation layer 110.

Each of the plurality of LED arrays 108 is mounted on the printed circuit board 105, and is electrically connected to each other. In an embodiment, the count of LED arrays 108 in the LED engine 100 is varied as per the required lumen output. In another embodiment, each of the plurality of LED arrays 108 contains a varied number of LEDs 125. In each of the LED arrays 108, each of the LEDs 125 is electrically connected to each other.

Further, the encapsulation layer 110 is configured to encapsulate each of the LED arrays 108 and the electrical connections 135 between the LED arrays 108 to protect the area proximal to the LED engine 100 from arc and spark, i.e., electrical discharges, generated by the LED engine 100. The encapsulation layer 110 is molded such that it contains at least one blister 115 and at least one planar portion 120.

The at least one blister 115 is configured to encapsulate at least one LED 125 of the LED arrays 108. In an embodiment, the encapsulation layer 110 includes a plurality of blisters 115 configured to encapsulate each LED 125 of the LED array 108. Further, each of the plurality of blisters 115 is also configured to function as lenses, i.e., as secondary optics, to facilitate transformation of the light emitted by the LEDs 125 of the LED arrays 108 into a desired light beam pattern. In an embodiment, each of the blisters 115 has transmittance in the range of 90% to 96%.

The at least one planar portion 120 of the encapsulation layer 110 is configured to encapsulate at least one electrical connection formed on the printed circuit board 105. In an embodiment, the encapsulation layer 110 includes a plurality of planar portions 120 configured to encapsulate the electrical connections 135 formed on the printed circuit board 105.

In an embodiment, the thickness of the encapsulation layer 110 is non-uniform. In another embodiment, the thickness of the planar portion 120 of the encapsulation layer 110 is lesser than the thickness of the blisters 115 of the encapsulation layer 110. In yet another embodiment, the thickness of each of the blisters 115 and the planar portion 120 is in the range of 2 mm to 6 mm. In a preferred embodiment, the thickness of the planar portion 120 of the encapsulation layer 110 is 3 mm and the thickness of each of the blisters 115 is 3.5 mm.

In one embodiment, the encapsulation layer 110 is of silicone.

In an embodiment, the encapsulation layer 110 occupies an area in the range of 40% to 80% of the printed circuit board 105.

In another embodiment, the shape of the blisters 115 is selected from the group consisting of circular, oval, eye-shaped, and elliptical.

In an embodiment, electrical wires 130 from each of the LED arrays 108 are guided through holes of the printed circuit board 105. In another embodiment, the electrical wires 130 are soldered to the LED arrays 108, and the portion of the encapsulation layer 110 encapsulating the soldered region of the printed circuit board 105 is elevated as compared to remaining portion of the encapsulation layer 110.

The present disclosure further envisages a process for encapsulating an LED (light emitting diode) engine having LED arrays and a printed circuit board. The LED arrays are mounted on the printed circuit board (PCB). The printed circuit board can have one or more than one LED array(s). Further, electrical connections are formed on the printed circuit board to connect the LED arrays to each other.

The process, of the present disclosure, is now elaborated in subsequent paragraphs.

Initially, a primer is coated on the LED arrays mounted on the printed circuit board to obtain a primer coated LED engine. The primer can be any primer known in the art. In case, there are more than one LED arrays, the primer is coated on each of LED arrays.

The so obtained primer coated LED engine is heated to a first predetermined temperature to obtain a heated primer coated LED engine. In an embodiment, the first predetermined temperature ranges from 40° C. to 80° C. Typically, the primer coated LED engine is heated for 5 minutes to 30 minutes.

The heated primer coated LED engine is then disposed in a mould. Preferably, the mould is made of a metallic material, typically stainless steel. The mould has a mould cavity defined within the mould. The shape and size of the mould cavity is determined as per the thickness and shape of the required encapsulation layer on the LED array.

Further, a silicone mixture is injected in the mould cavity of the mould at a predetermined pressure to encapsulate the LED array. In an embodiment, the predetermined pressure ranges from 200 MPa to 400 MPa. The injection of the silicone mixture results in the formation of a layer of the silicone mixture on the LED arrays and, if required, on the electrical connections formed on the printed circuit board of the LED engine. The mould cavity is configured such that the encapsulation layer is formed only on the LED array(s) and, if required, on the electrical connections of the LED engine.

In an embodiment, the mould has a single inlet and a single outlet.

The silicone mixture can be prepared by any suitable method known in the art. The silicone mixture is a 2-part silicone mixture having two silicones of different viscosities. In an embodiment, the silicone mixture is prepared by admixing a first silicone and a second silicone, and stirring the admixed the first silicone and the second silicone in a high precision vacuum machine. Typically, the pressure maintained in the vacuum chamber of the vacuum machine ranges from 0.5 Atm to 0.95 Atm. Due to stirring of the admixture in the vacuum machine, the air/gases entrapped in the admixture is/are removed.

The viscosity of the first silicone and the second silicone is different. In an embodiment, the viscosity of the first silicone ranges from 4000 cP to 5000 cP. Preferably, the viscosity of the first silicone is 4400 cP. In another embodiment, the viscosity of the second silicone ranges from 3000 cP to 3800 cP. Preferably, the viscosity of the second silicone is 3500 cP.

The viscosity of the silicone mixture so obtained ranges from 5000 cP to 5500 cP. In an embodiment, the viscosity of the silicone mixture so obtained is 5300 cP, if the viscosities of the first silicone and the second silicone are 4400 cP and 3500 cP respectively.

In another embodiment, the weight ratio of the first silicone and the second silicone in the silicone mixture is 1:1. More specifically, the first silicone and the second silicone are mixed in equal parts to obtain the silicone mixture.

In yet another embodiment, each of the first silicone and the second silicone is polydimethylsiloxane elastomer.

Further, the mould is heat treated in a thermal chamber for a predetermined time period. In an embodiment, the step of heat treating the mould in the thermal chamber includes the following sub-steps. The mould is maintained in the thermal chamber at a third predetermined temperature for a first predetermined time period. Subsequently, the mould is maintained in the thermal chamber at a fourth predetermined temperature for a second predetermined time period.

In an embodiment, the third predetermined temperature ranges from 40° C. to 60° C., and the first predetermined time period ranges from 25 minutes to 35 minutes. Preferably, the third predetermined temperature is 50° C., and the first predetermined time period is 30 minutes.

In another embodiment, the fourth predetermined temperature ranges from 110° C. to 130° C., and the second predetermined time period ranges from 25 minutes to 35 minutes. Preferably, the fourth predetermined temperature is 120° C. and the second predetermined time period is 30 minutes.

The heat treatment solidifies the silicone layer formed on the LED array(s).

Subsequent to heating, the heat treated mould is cooled to a second predetermined temperature. In an embodiment, the second predetermined temperature ranges from 20° C. to 35° C. Preferably, the second predetermined temperature is a room temperature or ambient temperature.

Subsequent to cooling, the mould is opened to obtain an encapsulated LED engine having an encapsulation on the LED array(s). The encapsulation is in the form of the silicone layer.

Preferably, the encapsulation is provided on the LED arrays as well as on the electrical connections formed on the printed circuit board of the engine.

The encapsulated LED engine 100, which is encapsulated using the process of the present disclosure, is shown in FIG. 1 to FIG. 6.

Referring to FIGS. 1 to 6, various patterns of the encapsulation layer 110 are shown. The encapsulation layer 110 is of the silicone mixture, and covers the LED arrays 108 and the electrical connections 135 formed on the printed circuit board 105. It should be noted that the patterns of the encapsulation layer 110 shown in FIGS. 1 to 6 are only for exemplary purposes. Various other patterns of the encapsulation layer 110 can also be formed using the process of the present disclosure, and are well within the scope and ambit of the present disclosure.

The encapsulated LED engine, of the present disclosure, better utilizes the space of a printed circuit board having a circular profile. Additionally, encapsulating the printed circuit board eliminates formation of air bubbles between the operative top surface of the printed circuit board and the encapsulation layer formed thereon.

The encapsulated LED engine, of the present disclosure, can be used in Zone-1 and Zone-2 applications. Specifically, in order to use the encapsulated LED engine 100 in Zone-1 application, the required thickness of the encapsulation layer 110 is greater than or equal to 3 mm. The LED engine can also be used in industrial LED luminaires. Further, the encapsulated LED engine provides desired light distribution pattern without requiring use of any lens or reflector. The encapsulation layer of the silicone does not affect the beam pattern produced by the LED array(s).

### TECHNICAL ADVANCEMENTS

The present disclosure described herein above has several technical advantages including, but not limited to, the realization of an encapsulated LED engine that:
is cost effective;
has reduced surface temperature;
has a simple configuration;
has improved life;
is not prone to early de-lamination due to frequent exposure to thermal shocks;
eliminates the requirement of secondary optics;
is modular;
better utilizes printed circuit board's space;
eliminates formation of air bubbles;
is light in weight; and
does not affect beam pattern of the LED arrays.

The foregoing disclosure has been described with reference to the accompanying embodiments which do not limit the scope and ambit of the disclosure. The description provided is purely by way of example and illustration.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the disclosure to achieve one or more of the desired objects or results.

Any discussion of documents, acts, materials, devices, articles or the like that has been included in this specification is solely for the purpose of providing a context for the disclosure. It is not to be taken as an admission that any or all of these matters form a part of the prior art base or were common general knowledge in the field relevant to the disclosure as it existed anywhere before the priority date of this application.

The numerical values mentioned for the various physical parameters, dimensions or quantities are only approximations and it is envisaged that the values higher/lower than the numerical values assigned to the parameters, dimensions or quantities fall within the scope of the disclosure, unless there is a statement in the specification specific to the contrary.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment as well as other embodiments of the disclosure will be apparent to those skilled in the art from the disclosure herein, whereby it is to be distinctly understood that the foregoing descriptive matter is to be interpreted merely as illustrative of the disclosure and not as a limitation.

We claim:

1. An encapsulated LED engine (100) comprising:
a printed circuit board (105);
a plurality of LED arrays (108), each of said LED arrays (108) mounted on said printed circuit board (105), and electrically connected to each other wherein, in each of said LED arrays (108), LEDs are electrically connected to each other; and
an encapsulation layer (110) configured to encapsulate each of said LED arrays (108) and the electrical connections (135) therebetween, wherein said encapsulation layer (110) includes:
at least one blister (115) configured to encapsulate at least one LED (125), and is further configured to transform the light emitted by said LED (125) into a desired light beam pattern; and
at least one planar portion (120) configured to encapsulate at least one electrical connection formed on said printed circuit board (105).

2. The LED engine (100) as claimed in claim 1, wherein said blister (115) has transmittance in the range of 90% to 96%.

3. The LED engine (100) as claimed in claim 1, wherein the thickness of said encapsulation layer (110) is non-uniform.

4. The LED engine (100) as claimed in claim 1, wherein the thickness of said planar portion (120) of said encapsulation layer (110) is lesser than the thickness of said blister (115) of said encapsulation layer (110).

5. The LED engine (100) as claimed in claim 1, wherein the thickness of each of said blister (115) and said planar portion (120) is in the range of 2 mm to 6 mm.

6. The LED engine (100) as claimed in claim 1, wherein said encapsulation layer (110) is of silicone.

7. The LED engine (100) as claimed in claim 1, wherein said encapsulation layer (110) occupies an area in the range of 40% to 80% of said printed circuit board (105).

8. The LED engine (100) as claimed in claim 1, wherein the shape of said blister (115) is selected from the group consisting of circular, oval, eye-shaped, and elliptical.

9. The LED engine (100) as claimed in claim 1, wherein said blister (115) is configured to act as lenses for each of said LEDs (125) of said LED arrays (108).

10. A process for encapsulating an LED engine (100) having a plurality of LED arrays (108) and a printed circuit board (105), said LED arrays (108) mounted on said printed circuit board (PCB) (105), said process comprising the following steps:
coating a primer on said LED arrays to obtain a primer coated LED engine;
heating said primer coated LED engine to a first predetermined temperature to obtain a heated primer coated LED engine;
disposing said heated primer coated LED engine in a mould;
injecting a silicone mixture into the mould cavity of said mould at a predetermined pressure to encapsulate said LED arrays of said LED engine;
heat treating said mould in a thermal chamber for a predetermined time period;
cooling said heat treated mould to a second predetermined temperature; and
opening said mould to obtain an encapsulated LED engine.

11. The process as claimed in claim 10, wherein said first predetermined temperature ranges from 40° C. to 80° C.

12. The process as claimed in claim 10, wherein said predetermined pressure ranges from 200 MPa to 400 MPa.

13. The process as claimed in claim 10, wherein said silicone mixture is prepared by admixing a first silicone and a second silicone, and stirring the admixture of said first silicone and said second silicone in a vacuum machine, wherein said first silicone and said second silicone have different viscosities.

14. The process as claimed in claim 13, wherein the viscosity of said first silicone ranges from 4000 cP to 5000 cP, and the viscosity of said second silicone ranges from 3000 cP to 3800 cP.

15. The process as claimed in claim 13, wherein said first silicone and said second silicone are polydimethylsiloxane elastomer.

16. The process as claimed in claim 13, wherein the weight ratio of said first silicone to said second silicone in said silicone mixture is 1:1.

17. The process as claimed in claim 10, wherein the step of heat treating said mould in said thermal chamber includes the following sub-steps:
maintaining said mould in said thermal chamber at a third predetermined temperature for a first predetermined time period; and
subsequently maintaining said mould in said thermal chamber at a fourth predetermined temperature for a second predetermined time period.

18. The process as claimed in claim 17, wherein said third predetermined temperature ranges from 40° C. to 60° C., and said fourth predetermined temperature ranges from 110° C. to 130° C.

19. The process as claimed in claim 17, wherein said first predetermined time period and said second predetermined time period range from 25 minutes to 35 minutes.
